(19) United States
(12) Patent Application Publication
(10) Pub. No.: US 2005/0121782 A1
(43) Pub. Date: Jun. 9, 2005

(54) Selectively adherent substrate and method for producing the same

(76) Inventors: Koichiro Nakamura, Tokyo (JP); Kazutomo Ikeuti, Tokyo (JP); Noriyuki Kawata, Tokyo (JP); Yasunori Arima, Tokyo (JP); Kenichi Nakama, Tokyo (JP)

Correspondence Address: LAW OFFICES;WHITHAM, CURTIS & CHRISTOFFERSON, P.C., SUITE 340, 11491 SUNSET HILLS ROAD, RESTON, VA, 20190, US

(21) Appl. No.: 11/002,428

(22) Filed: Dec. 3, 2004

(30) Foreign Application Priority Data
Dec. 5, 2003 (JP) P2003-406808
Dec. 25, 2003 (JP) P2003-430098
Oct. 27, 2004 (JP) P2004-312346
Oct. 29, 2004 (JP) P2004-315147

(51) Int. Cl. H01L 23/04

(52) U.S. Cl. 257/730; 438/118

(57) ABSTRACT

Concave parts arranged with a predetermined pattern on the surface of a plate substrate is formed. Wettability of the concave part surface is made to differ from that of the surface of a flat part between the concave parts. Particularly, in the case of an aqueous liquid, by forming water repellency film on the flat part, liquid can be stably retained on the concave part and prevented from spilling over to the adjacent concave part.

### BACKGROUND OF THE INVENTION

1. Field of the Invention

The present invention relates to a selectively adherent substrate having a function to selectively adhere or retain a specific substance to a microregion, which is used in the biotechnology field or microelectronics field, and particularly relates to a selectively adherent substrate having the surface controlled in wettability.

2. Description of Related Arts

On the application or organic related materials or biological materials to the field of electronics, it is highly expected that products Utilizing technologies such as molecular electronics, molecular memory, nano-biotechnology and the like will come into practical use. For this reason, as well as the requirement for highly densified integration of functional elements on a substrate (chip), more sophistication is desired of the function which selectively adheres or retains a specific substance to a specified part on the surface of a substrate.

Moreover, highly densified integration or highly densified arraying or functional elements has progressed in the field of life sciences in order for ultra-minute amounts or ultra-high sensitivity analysis which utilizes micro chemical reactors, genome analysis chips, protein analysis chips and the like; and consequently, selective adhesion property is also required for a substrate employed in such analyses. The substrate, which can selectively retain a liquid sample such as minutely small doses of a biological substance and the like on a specified site, will be made available for analyses or reactions. Such a selective function is realized by forming a site (functional coupling portion site) having a function to couple a molecule of a specific substance on the surface of a substrate. The skills of such site formation are, for example, disclosed in the following patent publications.
Publication of Japanese Translation of International Application No. JP H9-500569A
Japanese Patent Publication No. JP 2002-131327A
Japanese Patent Publication No. JP 2002-307801A
Japanese Patent Publication No. JP 2002-283530A
Japanese Patent Publication No. JP 2003-121442A
Japanese Patent Publication No. JP 2003-279572A

### SUMMARY OF THE INVENTION

Any of the methods disclosed in the above described patent publication, however, are methods for forming a pattern on the flat surface of a substrate, and have problems such as large fluctuations in the retained volume and inferior repeatable reproducibility while liquid samples in minute amounts are retained on a plurality or sites of the substrate surface because the functional coupling portion exists on the flat part. Further, there is another problem such as mixing of liquid samples adjacent to each other because the distance between the adjacent coupling parts is brought close as a result of highly densified arrangement of the coupling portions.

The present invention has been accomplished to solve those problems, and to provide a selectively adherent substrate in which a specific substance is preferable adhered or retained on a microregion in high density and minute amounts are reproducibility.

A selectively adherent substrate of the present invention has concave parts arranged with a predetermined pattern on the surface thereof. Liquid affinity of a specified part of a concave part surface or the concave part is made to differ from that of the substrate surface excluding the specified part. As a result, a specific substance can be stably adhered or retained on a specified part of the substrate due to the effects of convexoconcavity and affinity difference in the substrate.

Specifically, such the affinity difference may be provided by changing wettability on the surface or adherent coefficient with respect to a biological substance, between the specific part and the part other than the specific part.

It is preferable that each of the concave parts is formed as a recess by processing on a flat substrate. By directly processing on a surface of a glass substrate to form the recess, the concave parts of the predetermined arrangement can be easily formed.

It is preferable that a part excluding the specified part of the above described concave part surface is water repellent. On account of such a characteristic, an aqueous liquid becomes retainable on the concave part of the substrate.

Furthermore, in the case of a selectively adherent substrate having a flat part between the above described concave part and the concave part, wettability of all of the concave part surfaces is made to differ from that of the flat part surface. It is particularly preferable that the flat part surface is made water repellent. As a result, an aqueous liquid becomes retainable on the concave part of the substrate.

In the case of a selectively adherent substrate of which the above described concave parts are arranged densely, wettability of the specified part of the concave part surface is made to differ from that of the part excluding the specified part thereof. It is particularly preferable that the surface of a part excluding the specified bottom surface of the concave part is water repellent. As a result, a liquid becomes retainable on the concave part even if the distance between concave parts is brought close, and a liquid sample and the like can be retained in high density.

It is preferable that a difference in the contact angle with respect to water between the specified part of the above described concave part surface and the substrate surface excluding the specified part thereof is more than 20°. On account of the convexaconcave effect of the substrate surface, aqueous liquid can be stably retained at the specified part of the substrate in spite of smaller difference in the contact angle.

The difference in the contact angle is preferably greater than 50°, still preferably greater than 80°.

It is preferable that the above described water repellency surface is coated with at least one compound selected from a silane compound containing an alkyl group or a silane compound containing a fluoroalkyl group.

Further, it is preferable that each of the concave parts is formed by removing a predetermined part of a cover layer which is provided with a predetermined thickness so as to cover a surface of a basic substrate such that an aperture is formed on the surface of the cover layer. In such the case, the concave part surface is constituted by a wall surface formed by the aperture of the cover layer and the exposed surface of the basic substrate. The concave part may be formed by removing only a part of the cover layer formed on the basic substrate so that a predetermined arrangement pattern of the concave parts can be easily formed.

It is preferable that a surface of the cover layer is water repellent. By such the feature, a water-based liquid can be retained easily.

It is preferable that the thickness of the cover layer is not lese than 10 μm and not more than 100 μm. If the thickness is less than 10 μm, the concave parts does not provide sufficient function for retaining the liquid. If the thickness is more than 100 μm, it becomes difficult to process the concave part with accurate dimensions.

It is preferable that the difference in the contact angle to water between a surface of the basic substrate and the surface of the cover layer is larger than 20°. By an effect of the convexoconcave of the substrate surface, the water-based liquid can be retained reliably at the predetermined positions on the substrate only by a small difference in the contact angle.

More preferably the difference in the contact angle is larger than 50°, and further preferably larger than 80°.

Further, it is preferable that light transmittance of the basic substrate is larger than two times of the light transmittance of the cover layer. By providing low light transmittance in the part other than the concave parts, the detection sensitivity of the substance retained in the concave parts is improved by reducing stray light and increasing contrast, when the substance is analyzed and observed in optical methods.

It is preferable that the cover layer includes a layer with a black paint therein. By using such the material, both of the water repellency and the low light transmittance are simultaneously provided.

In the case of a selectively adherent substrate comprising the concave parts arranged with a predetermined pattern on the surface thereof and flat parts on the substrate surface between the concave parts, surface tension or the concave part surface is made to differ from that of the flat part surface. Particularly, the surface tension of the concave part is made greater than the surface tension of the flat part. As a result, liquid can be stably retained in the concave part.

It is preferable that a selectively adherent substrate comprising concave parts arranged with a predetermined pattern on the surface thereof, flat parts on the above described substrate surface between the concave parts and the above described flat part surface being water repellency, is produced by applying a solution containing a compound providing water repellency or hydrophilicity on a stamper and printing the solution from the stamper to the flat part.

Further, another forming method of the invention may comprise: a step of forming a water repellent coating layer containing a compound providing water repellency on a substrate surface, a step or forming a cover layer on the water repellent coating layer, a step of exposing a surface of the water repellent coating layer by removing partially the cover layer to form an aperture, a step of removing the water repellent coating layer by etching through the aperture and using the cover layer as mask, and a step of removing the cover layer.

Further, another forming method may comprise a step of forming a cover layer containing a compound providing water repellency on a substrate surface, and a step of partially removing the cover layer to form an aperture to expose the substrate surface.

By these forming methods, it is possible that the solution is easily adhered selectively only to the flat part and a partly water-repellent or hydrophilic film can be formed.

The selectively adherent substrate of the present invention, wherein concave parts are arranged on the surface thereof according to a predetermined pattern and the concave parts are made to differ from those of other parts different in wettability or surface tension, thereby a specific substance of a minute amount of a specific substance can be stably adhered or retained on the concave parts as well as preventing the specified substance from being mixed in the adjacent concave parts. Furthermore, a fluctuation in the adhered material can be reduced, and repeatable reproducibility can also be improved, thereby providing a selectively adherent substrate having excellent adherent and retaining functions.

A selectively biological substance adherent substrate or the present invention has concave parts arranged with a predetermined pattern on the surface thereof. A ratio of an adherent coefficient on the biological substance of a specified part of the concave part surface to that or the substrate surface excluding the specified part is greater than 10.

Herein, the adherent coefficient is defined by the product of the adhered area and the adhered film thickness, and when the above described adherent coefficient ratio is R, which the following formula is defined by.
R=(A₁×D₁)/(A₂×D₂)
However, the proviso that A₁ is an adhered area on the concave part surface, D₁ is an adhered film thickness on the concave part surface, A₂ is an adhered area on the flat part surface and D₂ is an adhered film thickness on the flat part surface.

As a result, a specific biological substance can be stably adhered or retained on a specific site of the substrate due to the effect of convexoconcavity and the difference in the adherent coefficient.

It is preferable that the above described specified part of the concave surface is coupled with a biological substance by at least one type or interaction selecting from a covalent bond, a hydrogen bond, a static electrical interaction, a dipole-dipole interaction, a stacking interaction and a hydrophobic interaction. With these interactions, the specific biological substance can be stably adhered or retained on the specified part or the substrate.

Furthermore, it is preferable that the specified part of the concave surface has at least one type of functional group selected from an amino group, a mercapto group, a carboxyl group, a sulfonicacid group, a hydroxyl group, an alkyl group and a phenyl group. With the presence of these functional groups, the specific biological substance can be stably adhered or retained on the specified part of the substrate.

It is preferable that the surface of the substrate excluding the specified part of the above described concave surface is water repellent. As a result of this, an aqueous specific biological substance can be retainable on a concave part of the substrate.

It is preferable that the surface of the water repellency is coated with at least one type selected from a silane compound containing an alkyl group or an aryl group, or a silane compound containing a fluoroalkyl group. With these compounds, a surface excellent in water repellency can be obtained.

It is preferable that a difference in the contact angle with respect to water between the specified part of the above described concave surface and the substrate surface excluding the specified part thereof is greater than 20°. With the effect of convexoconcavity of the substrate surface, the aqueous biological substance can be stably retained on the specified part of the substrate even if the contact angle difference is smaller.

In the case of a selectively biological substance adherent substrate comprising concave parts arranged with a predetermined pattern on the surface thereof and a flat part on the substrate surface between the concave parts, surface tension of the concave part surface in made to differ from that of the flat part surface. The surface tension of the concave part is particularly made greater than the surface tension of the flat part. As a result, the biological substance can be stably retained on the concave part.

### BRIEF DESCRIPTION OF THE DRAWING

FIG. 1 is a perspective view showing an example of a selectively adherent substrate of the present invention;

FIG. 2 is a schematic cross sectional view of an example of the selectively adherent substrate;

FIG. 3 is a view explaining the contact angle of a liquid droplet;

FIG. 4 is a perspective view showing another example of the selectively adherent substrate;

FIG. 5 is a view showing a state coated by water repellency film at the concave part;

FIG. 6 is a perspective view showing another example of the selectively adherent substrate;

FIG. 7 is a schematic cross sectional view or another example of the selectively adherent substrate;

FIG. 8 is a schematic view showing another example of the selectively adherent substrate;

FIG. 9 is a schematic cross sectional view of an embodiment of the selectively adherent substrate;

FIGS. 10A and 10B are views showing a state coated by water repellency film at the concave part; and

FIGS. 11A, 11A and 11C are views showing manufacturing process of the selectively biological substance adherent substrate of the present invention.

### DETAILED DESCRIPTION OF THE PREFERRED EMBODIMENTS

Embodiments or the present invention are described in detail as follows.

### First Embodiment

Materials used for the substrate of the present invention includes glass, ceramics, semiconductor, metal, resin and the lice. Types or glass usable include a quartz glass (coefficient of linear expansion α=0.5 ppm/K), a non-alkali glass, a soda-lime glass and the like. Further included are a low expansion glass ceramics such as Zerodur (SCHOTT, α=−2 ppm/K), NEOCERAM (Nippon Electric Glass, α=0.15 ppm/K) and the like, pyrex (Corning, α=3.25 ppm/K) BK7 (SCHOTT, α=7.1 ppm/K) and others.

Furthermore, a silicon provided in the form of wafer and a semiconductor such as InP, GaAs and the like are also available. Resin materials include an epoxy resin, an acrylic resin, a polycarbonate resin, a polyimide resin, a fluoric resin and the like. Even among these, it is most preferable to use a glass which is superior in heat resistance, transparency and chemical stability.

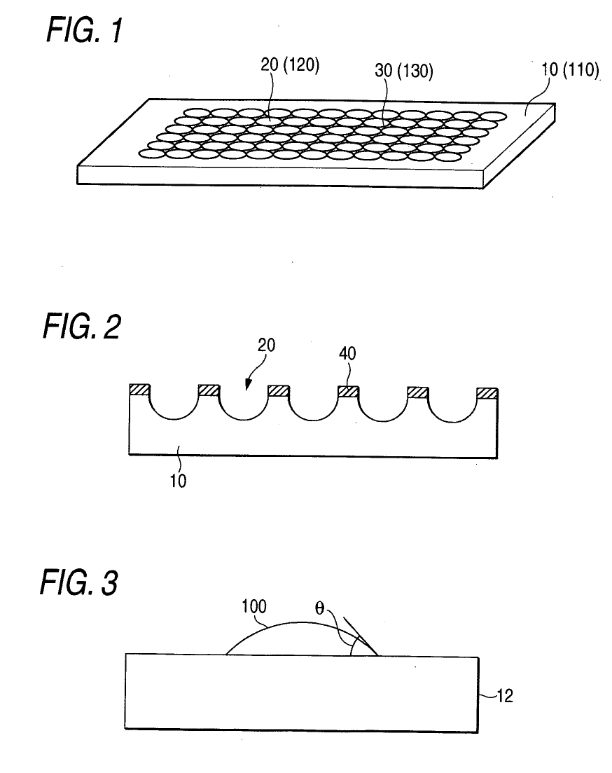

One embodiment of the selectively adherent substrate of the present invention is shown in FIG. 1. On the surface of a plate substrate 10, a plurality of concave parts 20 for retaining a liquid substance such as a solution or biological material substance and the like are formed. In this embodiment, there exists a flat part 30, which is the surface of the original plate substrate, between the adjacent concave parts. With the treatment for providing a difference in wettability with regard to a liquid to the concave part surface and to the flat part surface excluding the concave part of the substrate, thereby improving retainability of the liquid sample at the concave part 20.

FIG. 2 is a cross sectional view of the plate substrate 10 having the concave parts 20. A coated film 40 is formed on the flat part surface between the concave parts, and wettability of liquid retained by material of the coated 40 is selected different from that or the substrate surface (in this case, the concave part surface), thereby acquiring a difference in wettability.

By providing different wettability with concavities and convexities on the substrate surface and the parts corresponding thereto on the surface, an excellent characteristic can be provided for the substrate to which functional elements are mounted used in the microelectronics field and biotechnology field. The relationship of the wettabilly levels between the concave part surface and flat part surface of the substrate of the present invention depends on required functions; it may be preferable that the wettability of the concave part surface is greater than that of flat part surface, however, to the contrary, it may be preferable that the wettability of the concave part surface is smaller than that of flat part surface. Such a wettability relationship is particularly determined by the combination of materials which functionally interact with the substrate.

The substances to be selectively adhered can be widely selected for the selectively adherent substrate of the present invention by controlling the surface state thereof. The substrate is applicable to, in addition to solutions of biological substance and other solutions of chemical substances to a sample of those solutions containing living tissues such as a cell. It is further used for a solution employed in a liquid phase process such as metal plating, etching and the like in the electronics industry field, and a molten metal such as solder and the like, or a material for vacuum deposition and the like.

As a method for controlling wettability of the selectively adherent substrate of the present invention, the preferable method is to coat a compound having high or low wettability with respect to the specific parts to be retained, independently or as a mixture thereof, on the surface of the concave part or the flat part or the substrate.

First, it is described regarding a case where a substance functionally interacting with the substrate of the present invention is aqueous, a water-soluble material and an aqueous solution.

For providing a selectively adherent substrate in which wattability of the flat part surface is smaller than that of the concave part surface, a compound providing water repellency is coated on the flat part surface, or a compound providing hydrophilicity is coated on the concave part surface. Otherwise, a compound providing water repellency may be coated on the flat part surface together with coating a compound providing hydrophilicity on the concave part surface.

On the contrary, in the case of a selectively adherent substrate in which the wettability of the flat part surface is greater than that of the concave part surface is provided, a compound providing hydrophilicity is coated on the flat part surface, or a compound providing water repellency is coated on the concave part surface. Otherwise, a compound providing hydrophilicity may be coated on the flat part surface together with coating a compound providing water repellency on the concave part surface.

As materials which alter the wettability of the surface of the concave part or the flat part of the substrate in the present invention, a tetrafluoroethylene having water repellency group, a cyclic perfluoropolymer, a fluoroalkylsilane, an alkylsilane, silicone, a polysilane and the like can be served. By coating the surface of the flat part or the concave part of the substrate with these materials, the selectively adherent substrate having different wettabilities with respect to water at the concave part and the flat part can be provided.

As a compound having water repellency, a silane compound having water repellency group is preferably used. For example, exemplified is a silane compound having one, or two or more water repellency groups, for example, an alkyl group, a fluoroalkyl group and the like, in its molecule.

A silane compound having an alkyl group includes a chlorosilane containing an alkyl group such as
CH₃(CH₂)₃₀SiCl₃, CH₃(CH₂)₂₀SiCl₃, CH₃(CH₂)₁₈SiCl₃, CH₃(CH₂)₁₆SiCl₃, CH₃(CH₂)₁₄SiCl₃, CH₃(CH₂)₁₂SiCl₃, CH₃(CH₂)₁₀SiCl₃, CH₃(CH₂)₅SiCl₃, CH₃(CH₂)SiCl₃, CH₃(CH₂)₇SiCl₃, CH₃(C₂)₆SiCl₃, CH₃(CH₂)₅SiCl₃, CH₃(CH₂)₃SiCl₃, CH₃(CH₂)₃SiCl₃, CH₃(CH₂)₂SiCl₃, CH₅CH₂SiCl₃, (CH₃CH₂)₂SiCl₂, (CH₃CH₂)₃SiCl, CH₃SiCl₃, (CH₃)₂SiCl₂, and (CH₃)₃SiCl, an alkoxysilane containing an alkyl group such as CH₃ (CH₂)₃₀Si (OCH₃)₃, CH₃(CH₂)₂₀Si(OCH₃)₃, CH₃ (CH₂)₁₈Si(OCH₃)₃, CH₃ (CH₂)₁₆Si (OCH₃)₃, CH₃(CH₂)₁₄Si(OCH₃)₃, CH₃ (CH₂)₁₂Si (OCH₃)₃, CH₃ (CH₂)₁₀Si (OCH₃)₃, CH₃(CH₂)₉Si(OCH₃)₃, CH₃ (CH₂)₉Si(OCH₃)₃, CH₃ (CH₂)₇Si (OCH₃)₃, CH₃(CH₂)₆Si(OCH₃)₃, CH₃ (CH₂)₅Si (OCH₃)₃, CH₃ (CH₂)₄Si (OCH₃)₃, CH₃(CH₂)₃Si(OCH₃)₃, CH₃ (CH₂)₂Si (OCH₃)₃, CH₃CH₂Si(OCH₃)₃, (CH₃CH₂)₂Si(OCH₃)₂, (CH₃CH₂)₃SiOCH₃, CH₃Si(OCH₃)₃, (CH₃)₂Si(OCH₃)₂, (CH₃)₃SiOCH₃, CH₃(CH₂)₃₀Si(OC₂H₅)₂, CH₃(CH₂)₂₀Si(OC₂H₅)₃, CH₃(CH₂)₁₈Si(OC₂H₅)₃, CH₃(CH₂)₁₆Si(OC₂H₅)₃, CH₃(CH₂)₁₄Si(OC₂H₅)₂, CH₃(CH₂)₁₂Si(OC₂H₅)₃, CH₃(CH₂)₁₀Si(OC₂H₅)₃, CH₃(CH₂)₉Si(OC₂H₅)₃, CH₃(CH₂)₈Si(OC₂H₅)₃, CH₃(CH₂)₇Si(OC₂H₅)₃, CH₃(CH₂)₆Si(OC₂H₅)₃, CH₃(CH₂)₅Si(OC₂H₅)₃, CH₃(CH₂)₄Si(OC₂H₅)₃, CH₃(CH₂)₃Si(OC₂H₅)₃, CH₃(CH₂)₂Si(OC₂H₅)₃, CH₃CH₂Si(OC₂H₅)₃, (CH₃CH₂)₂Si(OC₂H₅)₃, (CH₃CH₂)₃SiOC₂H₅, CH₃Si(OC₂H₅)₃, (CH₃)₂Si(OC₂H₅)₂ and (CH₃)₃SiOC₂H₅, an acyloxysilane containing an alkyl group such as CH₃(CH₂)₃₀Si(OCOCH₃)₃, CH₃(CH₂)₂₀Si(OCOCH₃)₃, CH₃(CH₂)₁₈Si(OCOCH₃)₃, CH₃(CH₂)₁₆Si(OCOCH₃)₃, CH₃(CH₂)₁₄Si(OCOCH₃)₃, CH₃(CH₂)₁₂Si (OCOCH₃)₃, CH₃(CH₂)₁₀Si(OCOCH₃)₃, CH₃ (CH₂)₉Si(OCOCH₃)₃, CH₃(CH₂)₈Si(OCOCH₃)₃, CH₃(CH₂)₇Si(OCOCH₃)₃, CH₃(CH₂)₆Si(OCOCH₃)₃, CH₃(CH₂)₅Si(OCOCH₃)₃, CH₃(CH₂)₄Si(OCOCH₃)₃, CH₃(CH₂)₃Si(OCOCH₃)₃, CH₃(CH₂)₂Si(OCOCH₃)₃, CH₃CH₂Si(OCOCH₃)₃, (CH₃CH₂)₂Si (OCOCH₃)₂, (CH₃CH₂)₃SiOCOCH₃, CH₃Si (OCOCH₃)₃, (CH₃)₂Si (OCOCH₃)₂, and (CH₃)₃SiOCOCH₃ and an isocyanatesilane containing an alkyl group such as CH₃(CH₂)₃₀Si(NCO)₃, CH₃(CH₂)₂₀Si(NCO)₃, CH₃(CH₂)₁₀Si(NCO)₃, CH₃(CH₂)₁₆Si (NCO)₃, CH₃ (CH₂)₁₄Si(NCO)₃, CH₃(CH₂)₁₂Si(NCO)₃, CH₃(CH₂)₁₀Si (NCO)₃, CH₃(CH₂)₉Si(NCO)₃, CH₃ (CH₂)₈Si(NCO)₃, CH₃(CH₂)₇Si (NCO)₃, CH₃(CH₂)₆Si(NCO)₃, CH₃ (CH₂)₅Si(NCO)₃, CH₃(CH₂)₄Si (NCO)₃, CH₃(CH₂)₃Si(NCO)₃, CH₃ (CH₂)₂Si(NCO)₃, (CH₃CH₂)₂Si(NCO)₂, (CH₃CH₂)₃SiNCO, CH₃Si(NCO)₃, (CH₃)₂Si(NCO)₂, and (CH₃)₃SiNCO.

A silane compound having a fluoro group includes a trichlorosilane containing a fluoroalkyl group such as CF₃(CF₂)₁₁(CH₂)₂SiCl₃, CF₂ (CF₂)₁₀(CH₂)₂Si(Cl)₃, CF₃(CF₂)₉(CH₂)₂SiCl₃, CF₃(CF₂)₈(CH₂)₂SiCl₃, CF₃(CF₂)₇(CH₂)₂SiCl₃, CF₃(CF₂)₆(CH₂)₂SiCl₃, CF₃(CF₂)₅(CH₂)₂SiCl₃, CF₃(CF₂)₄(CH₂)₂SiCl₃, CF₃(CF₂)₃(CH₂)₂SiCl₃, CF₃(CF₂)₂(CH₂)₂SiCl₃, CF₃CF₂(CH₂)₂SiCl₃, and CF₃(CH₂)₂SiCl₃, a trialkoxysilane containing a fluoroalkyl group such as CF₃(CF₂)₁₁(CH₂)₂Si(OCH₃)₃, CF₃(CF₂)₁₀(CH₂)₂Si(OCH₃)₃, CF₃(CF₂)₉(CH₂)₂Si(OCH₃)₃, CF₃(CF₂)₈(CH₂)₂Si(OCH₃)₃, CF₃(CF₂)₇(CH₂)₂Si(OCH₃)₃, CF₃(CF₂)₆(CH₂)₂Si(OCH₃)₃, CF₃(CF₂)₅(CH₂)₂Si(OCH₃)₃, CF₃(CF₂)₄ (CH₂)₂Si(OCH₃)₃, CF₃(CF₂)₃(CH₂)₂Si(OCH₃)₃, CF₃(CF₂)₂ (CH₂)₂Si(OCH₃)₃, CF₃CF₂(CH₂)₂Si(OCH₃)₃, CF₃(CH₂)₂Si(OCH₂)₃, CF₃(CF₂)₁₁(CH₂)₂Si(OC₂H₅)₃, CF₃(CF₂)₁₀(CH₂)₂Si(OC₂H₅)₃, CF₃(CF₂)₉(CH₂)₂Si(OC₂H₅)₃, CF₃ (CF₂)₉(CH₂)₂Si(OC₂H₅)₃, CF₃(CF₂)₇(CH₂)₂Si(OC₂H₅)₃, CF₃ (CF₂)₆ (CH₂)₂Si(OC₂H₅)₃, CF₃(CF₂)₅(CH₂)₂Si(OC₂H₅)₃, CF₃ (CF₂)₄ (CH₂)₂Si(OC₂H₅)₃, CF₃(CF₂)₃(CH₂)₂Si(OC₂H₅)₃, CF₃ (CF₂)₂ (CH₂)₂Si(OC₂H₅)₃, CF₃CF₂(CH₂)₂Si(OC₂H₅)₃, and CF₃(CH₂)₂Si (OC₂H₅)₃, a triacyloxysilane containing a fluoroalkyl group such as CF₃(CF₂)₁₁(CH₂)₂Si(OCOCH₃)₃, CF₃(CF₂)₁₀(CH₂)₂Si(OCOCH₃)₃, CF₃(CF₂)₉(CH₂)₂Si(OCOCH₃)₃, CF₃(CF₂)₈(CH₂)₂Si(OCOCH₃)₃, CF₃(CF₂)₇(CH₂)₂Si(OCOCH₃)₃, CF₃(CF₂)₆(CH₂)₂Si(OCOCH₃)₃, CF₃(CF₂)₅(CH₂)₂Si(OCOCH₃)₃, CF₃(CF₂)₄(CH₂)₂Si(OCOCH₃)₃, CF₃(CF₂)₃(CH₂)₂Si(OCOCH₃)₃, CF₃(CF₂)₂(CH₂)₂Si(OCOCH₃)₃ CF₃CF₂ (CH₂)₂Si (OCOCH₃)₃, and CF₃ (CH₂)₂Si (OCOCH₃)₃, and a triisocyanatesilane containing a fluoroalkyl group such CF₃(CF₂)₁₁(CH₂)₂Si(NCO)₃, CF₃(CF₂)₁₀(CH₂)₂Si(NCO)₃, CF₃(CF₂)₉(CH₂)₂Si(NCO)₃, CF₃(CF₂)₈(CH₂)₂Si(NCO)₃, CF₃(CF₂)₇(CH₂)₂Si(NCO)₃, CF₃(CF₂)₆(CH₂)₂Si(NCO)₃, CF₃(CF₂)₅(CH₂)₂Si(NCO)₃, CF₃(CF₂)₄(CH₂)₂Si(NCO)₃, CF₃(CF₂)₃(CH₂)₂Si(NCO)₃, CF₃(CF₂)₂(CH₂)₂Si(NCO)₃, CF₃CF₂(CH₂)₂Si(NCO)₃, and CF₃(CH₂)₂Si(NCO)₃, .

Among these, a trialkoxysilane containing a fluoroalkyl group, particularly a fluoroalkyltriraethoxysailane and a fluoroalkyltriethoxysilane having the number of fluorine atoms of 13 to 22 are preferably used.

The surface of the concave part or the flat part of the selectively adherent substrate of the present invention is coated together with the concave part surface and the flat part surface with the materials exemplified herein independently or different materials thereon, thereby a difference in the contact angle with respect to water is consequently provided to the above described patterned parts having different wettability.

The selectively adherent substrate of the present invention, differs from the substrates disclosed in the above described patent publications, and beforehand has concave parts on the substrate and the concave part itself particularly has a function to retain liquid. The liquid retaining function is evaluated by a contact angle by a liquid on a solid substrate surface. The contact angle θ is defined by a contacting angle formed by a liquid drop 100 dropped on the surface of a solid substrate 12 as exemplified in FIG. 3.

The present invention can provide a selectively adherent substrate excellent in quantitativity and reproducibility and having a highly densified coupling portion by increasing the difference in the contact angles between the concave part and the flat part being set at 20° or more. In the case of a flat substrate surface without a concave part, a much greater contact angle difference is required, according to the invention, the applicable range of water repellency materials becomes broader. The difference in the contact angles is further preferably greater than 50°, still more preferably greater than 80°. Consequently, a selectively adherent substrate further excellent in selectivity can be provided.

Moreover, the maximum value of the contact angle is 180°. In such a case, liquid does never wet a substrates and becomes a spherical liquid drop. In the selectively adherent substrate of the present invention, ideal contact angle at the part provided with water repellency is 180°.

Further, the selectively adherent substrate of the present invention is characterized in that the concave part surface differs from the flat part surface in surface tension. As a method for providing such surface tension difference, the following method is described.

For example, since the critical surface tension of glass is approximately 100 mN/m, by coating the flat part with a compound having water repellency group makes the method achievable. The specific example of the water repellency group is exemplified by an ethylene group (critical surface tension: 31 mN/m), a methyl group (20 mN/m), a trifluoromethyl group (6 m/ml) and the like. By coating with such a compound, the surface tension or the substrate surface is made preferably greater than 20 mN/m, further preferably greater than 40 mN/m and most preferably greater than 60 N/m, and the substrate selectively retaining the liquid material can be consequently provided. A compound reducing surface tension of a glass is exemplified by a compound having water repellency group.

Although, up until now, described have been cases where a substance functionally interacting with the substrate of the present invention is aqueous, a water-soluble material and an aqueous solution, the substance is not limited thereto. The present invention is applicable to a case where a substance functionally interacting with the substrate is an oil base, a water-nonsoluble material and an non-aqueous solution. For providing a substrate in which the wettability of the flat part surface is smaller than that of the concave part surface, a compound providing oil repellent may be coated on the flat part surface, or a compound providing lipophilicity may be coated on the concave part surface. Otherwise, a compound providing oil repellent may be coated on the flat part surface together with coating a compound providing lipophilicity to the concave part surface.

For providing a substrate in which the wettability of oil base or non-aqueous solution on the flat part surface is greater than that of the concave part surface, a compound providing lipophilicity may be coated on the flat part surface, or a compound providing oil repellent may be coated on the concave part surface. Otherwise, a compound providing hydrophilicity may be coated on the flat part surface together with a compound providing oil repellent to the concave part surface.

The substrate of the prevent invention is characterized by having concave parts regularly arranged. The shape, height, width, and density of the concave part may be any form necessary to the functional devices employing the substrate of the present invention. The shape or the concave part includes a spherical dent, a cone, a trigonal pyramid, a square pyramid, a groove, a cylinder, a line, a Y branched line and the like. When the arranged concave part is a spherical dent, a cone, a trigonal pyramid, a square pyramid, a groove, or a cylinder, the arranged concave parts are 4 or more per 1 cm², preferably 100 or more, and further preferably 10,000 or more. Moreover, in the case of a liner concave part, the line width is 3,000 micro-meter or less, preferably 10 micro-meter or less. Thus, the substrate having a highly densified fine pattern structure can be obtained.

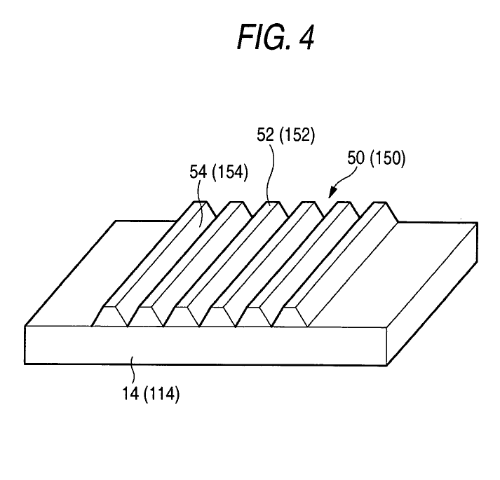

The structure of the selectively adherent substrate of the present invention is not limited to the embodiment shown in FIG. 1. A substrate structured so that a convex part 50 on the surface of a substrate 10 is formed as shown in FIG. 4 can be used. For example, such a structure may be formed by stacking layers with an appropriate thickness on the substrate surface and then partially removing these layers. In such a structure, it may also be used as a substrate or the present invention by making the wettability of a convex part surface 52 different from that of the bottom or a slant face 54.

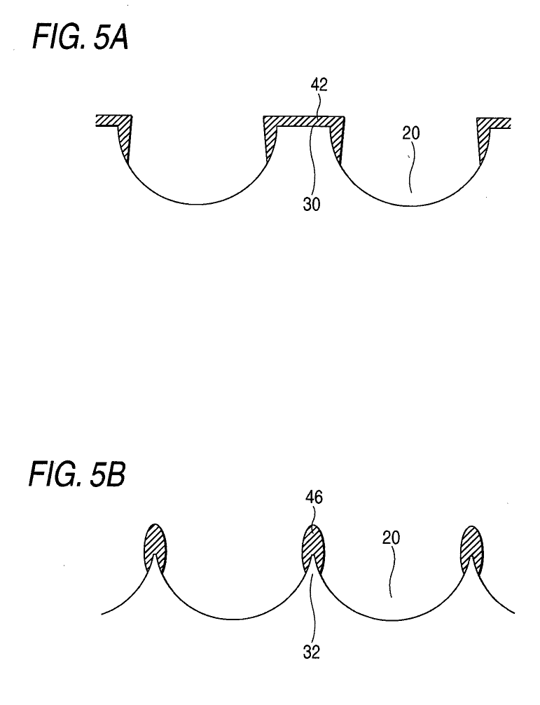

Furthermore, a part of the concave part of the substrate of the present invention may be water repellency. For example, in FIG. 5 which is an enlarged sectional view of the substrate surface part, water repellency film 42 may be produced not only on a flat part 30 but also the upper side in a concave part 20 as shown in FIG. 5(a).

There exists the flat part an the substrate surface in the above example; however, when the concave part 20 is provided densely as shown in FIG. 5(b), water repellency film 46 may be provided on a pointed crown part 32 although no flat part exists. Even where the concave part of the substrate surface is brought close and highly densified, and an area of the part having water repellency is relatively reduced, the selectively adherent substrate having coupling portions excellent in quantitativity and reproducibility can be provided.

A method for producing the selectively adherent substrate of the present invention is described hereinafter. A first method is that the concave part of the substrate surface is processed beforehand, followed by coating a substance changing wettability on the concave part or the flat part. A second method is that the plate substrate surface is coated beforehand by a material changing wettability, followed by processing the concave part. With any of these methods, a substrate having different wettability parts can be obtained. As a method for producing the substrate having regularly arranged concave parts, a combined method of formation of a mask-pattern such as photolithography, electron beam lithography, proton-beam lithography, X-ray lithography and the like can be exemplified, and a concave part formation such as a laser abrasion method, a wet etching method and the like.

As a method for coating a material changing the wettability on the substrate, a wet method and a dry method (vacuum method) can be exemplified. The wet method includes a spin-coating method, a dip-coating method, a spray-coating method, a flow-coating method, a meniscus-coating method, a gravure printing method, a flexographic printing method, a nano-imprinting method, a soft lithography method, a microcontact printing met-hod and the like. The soft lithography method is particularly a simple and low cost method to selectively adhere a solution only on the flat part of the substrate surface having concave parts.

The dry method (vacuum method) includes an evaporation method, a spattering method, an ion-beam method, a CVD method, a MOCVD method and the like. By combining these methods, a substrate having concave or convex parts patterned with different wettability parts can be obtained.

The specific examples are described hereinafter.

### EXAMPLE 1

(Preparation of Coating Solution for a Water Repellent Layer)

The coating solution for water repellent layer (hereinafter, the solution is referred to as Liquid A) was prepared by mixing an ethanol (97.68 parts by weight), heptadecafluorodecyltrimethoxysilane (0.02 parts by weight), tetraethoxysilane (0.3 parts by weight) and concentrated sulfuric acid (2.0 parts by weight), followed by stirring for 30 minutes at a room temperature.

(Substrate Manufacturing)

Liquid A was coated on the quartz glass substrate (thickness 2 mm, size 50 mm×50 mm) by a spin-coating method. After being dried for 24 hours at a room temperature, Cr film and AU film were formed by a spattering method, followed by photoresist coating by a spin-coating method. Thereafter, the photoresist film was exposed with a pattern having apertures of 2500 in total arranged in a grid pattern such as 50 in the longitudinal direction and 50 in the transverse direction, followed by developing and then removing the exposed parts of the photoresist. Au film and Cr film were etched by using the photoresist as a mask to form apertures.

The glass substrate with the mask was washed with ultra pure water (specific resistance: 18 MsΩ·cm), followed by etching with 49% hydrofluoric acid. Thereafter, the photoresist film was peeled of: by NaOH aqueous solution after being washed by ultra pure water. Furthermore, the Cr mask was peeled away by using an aqueous solution of nitric acid diammonium cerium after is Au film was peeled away by using an aqueous solution of iodine/ammonium iodide.

The selectively adherent substrate obtained is shaped as shown in the schematic FIG. 1, and its cross sectional shape was schematically shown by FIG. 2. The diameter of the spherical concave part was 50 μm, its density was 100/cm² (hereinafter, referred to as Substrate A).

For comparison, Substrate B was obtained by producing a substrate according to the manner described above except that coating of water repellency film with Liquid A was not performed.
[0058]-(i)
   (Evaluation of Wettability of Substrate)

When measuring the contact angle (, refer FIG. 3,) with respect to water on Substrate A, the angle was 70° at the surface of the flat part, and 10° at the surface of the concave part, and the difference in the contact angle with respect to water between the concave part and the flat part was 60°. When ultra pure water was dropped on the spherical concave part or Substrate A by a microsyringe, the water was retained in the spherical concave part. When the water was dropped in the amount more than the capacity of the spherical concave part, the water swelled as a convexity due to the surface tension of the flat part surface being greater than that of the spherical dent concave part surface, and was retained without spilling over to the flat part. On the other hand, the contact angle of the flat part of Substrate B was 5°. When ultra pure water was dropped on the spherical concave part by a microsyringe, the water drained out to the flat part and was not retained in the spherical concave part.

### EXAMPLE 2

Cr film and AU film were formed by a spattering method on the quartz glass substrate (thickness 2 m=, size 50 mm×50 mm), followed by photoresist coating by a spin-coating method. Thereafter, the photoresist film was exposed with a pattern having apertures of 2500 in total arranged in a grid pattern such as 50 in the longitudinal direction and 50 in the transverse direction, followed by developing and then removing the exposed parts of the photoresist. Au film and Cr film were etched by using the photoresist film as a mask to form apertures.

The glass substrate with the mask was washed with ultra pure water (specific resistance: 18MΩ·cm) followed by etching with 49% hydrofluoric acid. Thereafter, the photoresist film was peeled off by NaOH aqueous solution after being washed by ultra pure water. Furthermore, Cr film was peeled away by using an aqueous solution of nitric acid diammonium cerium after the Au mask was peeled away by using an aqueous solution of iodine/ammonium iodide.

The spherical concave part obtained was 50 μm in the diameter, and its density was 100/cm² (Substrate C). On the flat part, by a soft lithography method described below, water repellent layer was formed on the flat part of Substrate C.

The plate of polydimethylsiloxane (PMS) having a smooth surface and thickness of approximately 1 mm was employed as a stamper. Liquid A was poured in a flat-dish type vessel, followed by contact of one side of the stamper surfaces to the liquid. Thereafter, the stamper was made to contact with the surface of Substrate C to print Liquid A on the stamper surface to the surface of Substrate C. Consecutively, it was dried at a room temperature for 24 hours, then substrate D hating a water repellency flat part was obtained. The selectively adherent substrate obtained had a structure (FIG. 1, FIG. 2) similar to the shape of Example 1.

By measurement of the contact angle with respect to water on the Substrate D, the angle was 105° at the surface of the flat part, and 50 at the surface or the concave part, and the difference in the contact angle with respect to water between the concave part and the flat part was 100°. When ultra pure water was dropped on the spherical concave part or Substrate D by a microsyringe, the water was retained in the spherical concave part. When the water was dropped in the amount more than the capacity of the spherical concave part, the water was swelled as a convexity due to the surface tension of the flat part surface being greater than that of the spherical dent concave part surface, and was retained without spilling over to the flat part.

### EXAMPLE 3

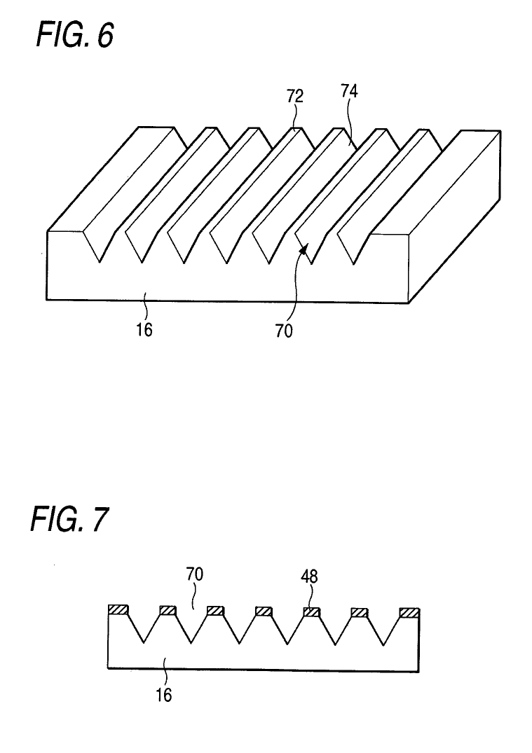

In the present Example, described is the case where a groove 70 having a V-shape cross section (hereinafter, referred au to V Groove) on a silicone substrate 16 as shown in FIG. 6. The photoresist mask having a slit-like aperture on the silicone substrate (thickness 2 mm, size 25 mm×25=mm) was formed, followed by formation of V Groove of approximately 1000 on the substrate surface by an isotropic wet etching method. A slant face 74 of the side of the V Groove corresponded to the (1,1,1) face of silicone crystal, and the depth of the groove was 20.15 μm, the width was 14.3 μm, the interval between adjacent grooves was 24.7 μm, and a flat part 72 (a width remaining without being ethched) on the summit of the “ridge” between the V Grooves was approximately 5.0 μm (Substrate A2).

A film was formed on the flat part with an alcohol solution of polyakyleneoxide-modified silicone as the agent providing hydrophilicity by a soft lithography method employing PDMS as a stamper in the same manner as Example 1 (Substrate B2). After film formation, it was dried at a room temperature for 24 hours, and then the substrate of the present invention was obtained. The schematic cross sectional view of the selectively adherent substrate formed with a hydrophilic film 48 is shown in FIG. 7.

When measuring the contact angle with respect to water, the angle was 5° at the surface of the flat part providing hydrophilicity, and 60° at the surface of the concave part, and the difference in the contact angle with respect to water between the concave part and the flat part was 55° (Substrate 52). When ultra pure water was dropped on Substrate B2 by a microsyrixge, the water was spread on the surface of the flat part between the grooves and retained, but not adhered to the concave part.

### EXAMPLE 4

The explanation will be given to an example where a light shielding treatment is conducted on the parts other than the concave parts.

Black paint providing water repellency is used in this example. The used black paint contains carbon black, thermoplastic resin, pigment, solvent and the like. Table 1 shows compositions of four types (C1-C4) or the used black paints.

TABLE 1
Composition (% by weight)

| Black | Thermoplastic | | | Carbon | | High boiling |
|---|---|---|---|---|---|---|
| paint | resin | Paraffin | Pigment | Black | Silica | Solvent |
| C1 | 40 | 5 | 0 | 1-10 | 5 | 30 |
| C2 | 40 | 5 | 10 | 5 | 5 | 30 |
| C3 | 20 | | 50 | 5 | | 20 |
| C4 | 30 | 5 | 40 | 5 | | 20 |

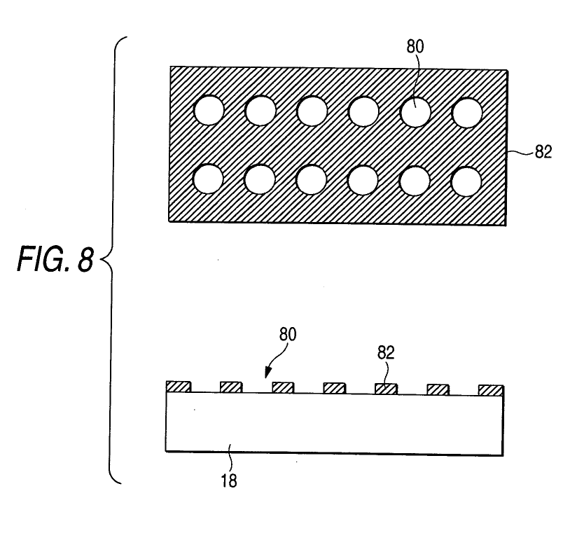

The above black pains were painted on washed non-alkali glass substrates (NA32, fabricated by NH TECHNOGLASS, thickness 0.7 mm, size 25 mm×75 mm) by screen printing method. On the screen, 50 circle patterns of 2.5 mm diameter are arranged in 5 lines×10 rows at 4 mm pitch. As shown in FIG. 8, 50 unpainted parts, each having circle pattern of 2.5 mm diameter, are formed at 4 mm pitch on a substrate 18 on which a black paint 90 is painted. The substrate 18 was dried in an internal air circulation oven heated at 100° C. for 30 minutes. Thereafter, the substrate was treated with ultra-sonic treatments for 5 minutes in ethanol, for 5 minutes in 0.1 mol KOH aqueous solution and then for 5 minutes in ultra pure water.

The level-difference between the circular unpainted part 90 and the painted parts formed in the circumference or the unpainted part 80 was measured by contact needle thickness meter. The thickness of the black paint 82 was 20 μm. As shown in Table 2, the contact angles of the black painted parts in Substrate D1 through D4 were not less than 110′, and the contact angles of glass surfaces on the unpainted parts were less than 10°. Therefore, the contact angle differences were observed to be not less than 80°. No light transmittance was detected at the black painted parts, and the light transmittance at the unpainted parts was about 90%.

As described above, the selectively adherent substrate may be fabricated by covering the surface of the basic substrate having hydrophilicity with a material providing water repellency and then removing a part of the cover so as to form an aperture exposing the hydrophilic basic substrate. In this case, the concave part surface is constituted by side wall surface of the aperture in the covered layer and the exposed surface of the basic substrate. Consequently, the flat part around the concave part and the side wall surface of the concave part provide water repellency and only the bottom surface of the concave part provides hydrophilicity.

Further, by using the black paint, the light transmittance in the water repellent part can be reduced to substantially 0. The detection sensitivity of the substance retained in the concave parts is improved by reducing stray light and increasing contrast, when the substance adhered in the substrate is analyzed and observed in optical methods such as fluorometric analysis, emission spectral analysis and absorptiometric method.

TABLE 2

| | | Contact Angle (°) | | Transmittance (%) | |
|---|---|---|---|---|---|
| | Black | Painted | Unpainted | Painted | Unpainted |
| Substrate | paint | part | part | part | part |
| D1 | C1 | 110 | <10 | 0 | 90 |
| D2 | C2 | 112 | <10 | 0 | 90 |
| D3 | C3 | 114 | <10 | 0 | 90 |
| D4 | C4 | 112 | <10 | 0 | 90 |

### EXAMPLE 5

While the bottom surface or the concave part was the exposed surface of the basic substrate on which no specific treatment was performed in Example 4, the bottom surface of the concave part was processed so as to form a recess in the present example, The selectively adhered substrates of Example 4 (Substrates D1 to D4) to which the light shield layer of the black paint was applied were washed with ultra pure water (specific resistance: 18 MΩ·cm). Thereafter, the substrates were processed by etching for 5 minutes while the black painted layer made of a mixture (Liquid F) consisting of 20 wt % of hydrofluoric acid, 2 wt % of ethylene diamine tetra-acetic acid (EDTA) and 0.5 wt % of sodium dodecylbenzenesulfonate, was served as a mask. Then, substrates E1 through E4 were obtained by washing with ultra pure water. The level difference between the flat part and the etched part in the glass substrates was measured to be 50 μm by the contact needle thickness meter.

TABLE 3

| | Black | | | | |
|---|---|---|---|---|---|
| | paint | Contact Angle (°) | | Transmittance (%) | |
| | painted | Painted | Unpainted | Painted | Unpainted |
| Substrate | substrate | part | part | part | part |
| E1 | D1 | 110 | <10 | 0 | 90 |
| E2 | D2 | 112 | <10 | 0 | 90 |
| E3 | D3 | 114 | <10 | 0 | 90 |
| E4 | D4 | 112 | <10 | 0 | 90 |

### EXAMPLE 6

While Example 6 is related to the same selectively adherent substrate as Examples 1 and 2, another manufacturing method is utilized.

A coating liquid for water-repellency coating was made by mixing ethanol (97.68 wt parts), and heptadecafluoro-decyl-trichlorosilane (0.02 wt parts), and stirring the mixture for 30 minutes under room temperature. (Liquid G) Liquid G was applied to anon-alkali glass substrate (thickness: 0.7 mm, size 25 mm×75 mm) by dip-coating method. The substrate was dried in the internal air circulation oven heated at 150° C. for 30 minutes. Thereafter, the substrate was treated with ultra-sonic treatments for 5 minutes in ethanol, for 5 minutes in 0.1 mol KOH aqueous solution and then for 5 minutes in ultra pure water. (Substrate H) The contact angle of the substrate was measured to be 120°.

Black paint (C2, see Table 1) was painted on Substrate H by screen printing method. On the screen, 50 circle patterns of 2.5 mm diameter are arranged in 5 lines×10 rows at 4 mm pitch. On the substrate on which the black paint is painted, unpainted parts, each having circle pattern of 2.5 m diameter, are formed at 4 mm pitch. The substrate was dried in the internal air circulation oven heated at 100° C. for 30 minutes.

The substrate was washed with ultra pure water (specific resistance: 18 MΩ·cm), followed by etching with Liquid F (see Example 5) for 5 minutes. Thereafter, the substrate was washed with ultra pure water again. (Substrate I)

The level difference between the flat part and the etched part in Substrate I was measured to be 50 μm by the contact needle thickness meter.

By washing Substrate I with a black paint removal liquid so as to remove the black paint, the glass substrate was obtained. In the glass substrate, the flat part is coated with transparent water repellency and the concave part having 50 μm depth provides hydrophilicity. The contact angle to water in the water repellency coated part was not less than 110°, the contact angle in the glass surface in the concave part was less than 100. Therefore, the contact angle difference was observed to be not less than 80°. The light transmittances were not less than 90% both in the water repellency Part and the concave part.

The black paint as described in the above embodiment is an example. The black paint of the invention is not limited to the above example. Since the covered layer is to be finally removed, it is sufficient if the covered layer is not corroded by Liquid F, and can be easily removed after pattern forming and etching.

In the Examples described above, liquid was targeted as the Specific substance for the substrate adhering and retaining a specific substance to a microregion in high density. The substrate can be utilized for reactions and measurements of minute amounts of biological substances. The present invention, however, is not limited to such applications. It can also be used to provide functional elements having special function applying biological substances and organic materials to electronics field. Furthermore, it is also possible to be used for selective adhesion of an inorganic material such as a metal and the like, for example, for plating technology and the like.

### Second Embodiment

Second embodiment of the selectively adherent substrate of the present invention is described below.

Basic structure of a substrate of second embodiment is the same as that of first embodiment as shown in FIG. 1.

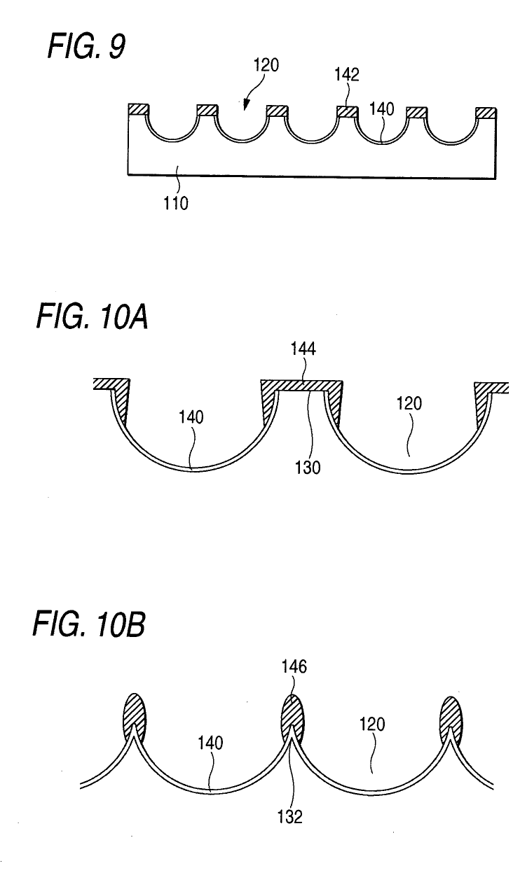

FIG. 9 is a cross sectional view of the plate substrate 110 having a concave part 120 and a flat part 130. A coated film 140 is formed on the surface inside the concave parts, and a coated film 142 comprised of a material different from that used for the coated film 140 is formed on the slat part surface between the concave part. Although the coated film 190 or the concave part has greater adherability with respect to a biological substance, on the contrary, a material with small adherability with respect to a biological substance is selected for the coated film 142 on the flat part, thereby the biological substance can be stably retained in the concave part.

A selectively biological substance adherent substrate of the present invention has concave parts arranged with a predetermined pattern on the surface thereof. A ratio of an adherent coefficient to biological substance of a specified part of the concave part surface to that of the substrate surface excluding the specified part is greater than 10.

Herein, the adherent coefficient is defined by the product of the adhered area and the adhered film thickness, and when the above described adherent coefficient ratio is R, which the following formula is defined by.
R=(A₁×D₁)/(A₂×D₂)

With the proviso that A₁ is an adhered area on the concave part surface, D₁ is an adhered film thickness on the concave part surface, A₂ is an adhered area on the flat part surface and D₂ is an adhered film thickness on the flat part surface.

In order to satisfy the above described requirement, a means may be applied in the present invention wherein the substrate surface excluding the specified part of the concave part surface is made water repellent. Moreover, the specified part of the concave part surface has a functional group to selectively fix a compound coupling a biological substance and the specified part.

The biological substance includes nucleic acids such as DNA, RNA and the like, a protein, a lipid, a carbohydrate, a vitamin, an enzyme and so on; and as a functional group selectively immobilizable of those substances, the following groups are exemplified. Namely an amino group, a mercapto group, a carboxyl group, a sulfonic acid group, a hydroxyl group, an alkyl group and a phenyl group exist. As a result of having such type of functional group, the biological substances and the compounds coupling therewith can be selectively immobilized on the substrate.

As a compound having an amino group exemplified is a lysine, a polyamine, an aminosilane and the like. An aminosilane compound is exemplified by an aminopropyltrimethoxysilane, an aminopropyltriethoxysilane, an (aminoethylaminomethyl)phenethyltrimethoxysilane, an N-(2-aminoethyl)-3-aminopropylmethyldimethoxysilane, an N-(2-aminoethyl)-3-aminopropyltrimethoxysilane, an N-(6-aminohexyl)aminopropyltrimethoxysilane, an N-(6-aminohexyl)aminopropyltrimethoxysilane, an N-(2-aminoethyl)-11-aminoundecyltrimethoxysilane, an aminophenyltrimethoxysilane, an N-3-[(amino (polypropylenoxy)aminopropyltrimethoxysilane, an aminopropylsilanetriol, an (3-trimethoxysilylpropyl)diethylenetriamine and the like. Those aminosilane compounds may also be used in the hydrolyzed condensified.

As a compound having a mercapto group exemplified is an alkylthiol, a mercaptosilane and the like. A mercaptosilane compound is exemplified by a 3-mercaptopropyltrimethoxysilane, a 3-mercaptopropyltriethoxysilane and a 3-mercaptopropylmethyldimethoxysilane. A bis [3-(triethoxysilyl) propyl] tetrasulphido may also be used. These silane compounds may also be used in the hydrolyzed condensified.

As a compound having a carboxyl group exemplified is an alkylcarboxylic acid, a carboxylsilane and, for example, a carboxyethylsilanetriol sodium salt.

As a compound having a hydroxyl group exemplified is a N-(hydroxyethyl)-N-methylaminopropyltrimethoxysilane, a hydroxymethytriethoxysilane, a 2-[hydroxy(polyethyleneoxy)propyl]diphenylketone, a N-(3-triethoxysilylpropyl)gluconamide and a N-(triethoxysilylpropyl)-o-polyethyleneoxideurethane. These silane compounds may also be used being as condensed hydrolysis.

As a compound having a phenyl group exemplified is a trimethoxyphenylsilane, a triethoxyphenylsilane, a trichlorophenylsilane and a pentafluorophenyltriethoxysilane. These silane compounds may also be used as condensed hydrolysis.

As a compound having simultaneously an amino group, a carboxyl group and another group exemplified is an amino acid and olygomer thereof such as oligopeptide and polypeptide. As an amino acid, exemplified are a glycine, an alanine, a valine, a leucine, an isoleucine, a serine, a threonine, a cysteine, a cystine, a methionine, a phenylalanine, a tyrosine, a tryptophan, a proline, an asparagine, a glutamine, an aspartic acid, a glutaminic acid, a lysin, a histidine, an arginine and the like.

By a convexoconcavity of the substrate surface and providing a different adherability to the parts corresponding thereto on the surface, an excellent characteristic can be rendered to the substrate which includes functional elements used in microelectronics fields and biotechnology fields.

Applicable materials to be selectively adhered for the selectively adherent substrate of the invention can be widely selected by controlling the surface state thereof. The substrate is applicable, in addition to solutions of a biological substance and other solutions of a chemical substance, to a sample of these solutions mixed with living tissues such as cell.

As a method to control adherability of the selectively adherent substrate of the present invention, preferable is to coat a compound having high adherability to the specific biological substance, independently or as a mixture thereof, on the surface of the concave part of the substrate. Furthermore, it is preferable that a compound having low adherability to the biological substance is coated on the flat part surface other than the concave part of the substrate. Since a biological substance is generally aqueous, a water repellent material can be selected as a material having low adherability.

As a material to provide water repellency to the flat part surface of the substrate of the present invention, exemplified are a tetrafluoroethylene having water repellency group, a cyclic perfluoropolymer, a fluoroalkylsilane, an alkylsilane, silicone, a polysilane and the like as described in Embodiment 1. By coating the surface of the flat part of the substrate with these materials, the substrate having small adherability to water at the flat part compared with the concave part can be provided.

As a compound having a water repellency group, a silane compound having water repellency group is preferably used. Exemplified is a silane compound having one, or two or more water repellency groups, for example, an alkyl group, a fluoroalkyl group and the like, in its molecule.

For a silane compound having an alkyl group and a silane compound having a fluoro group, the materials as described in Embodiment 1 are also applicable in Embodiment 2.

The surface of the flat part of the substrate of the present invention is coated with the materials as exemplified above, independently or in combination of different materials thereof, thereby the biological substance consequently becomes difficult to adhere to the flat part. Accordingly, the biological substance sample hardly penetrates to adjacent concave part even if the concave parts are closely located to each other.

Embodiment 2 can provide a selectively adherent substrate excellent in quantitativity and reproducibility and having a highly densified coupling portion by increasing the difference in the contact angles between the concave part and the flat part buing set at 20° or more. In the case of a flat substrate surface without a concave part, a much greater contact angle difference is required, according to the invention, the applicable range of water repellency materials becomes broader. The difference in the contact angles is further preferably greater than 50°, still more preferably greater than 80°. Consequently, a selectively adherent substrate further excellent in selectivity can be provided.

The substrate of the present invention may be such that a regularly arranged concave part is coated with a compound having a hydrophobic group and the flat part is coated with a compound having water repellency group of which surface tension is smaller than that or the compound having a hydrophobic group. Such a substrate can selectively adhere a biological substance having a hydrophobic group to the concave part. For example, the substrate can be achieved by coating the concave part with an aforementioned alkylsilane compound or hydrolysate thereof along with coating the flat part with a fluoroalkylsilane compound or hydrolysate thereof. Use of this type or substrate makes it possible to utilize the hydrophobic interaction between the biological substance having a hydrophobic group and the concave part surface coated with the hydrophobic alkylsilane compound, thereby a substrate excellent in adhering selectivity can be provided.

Furthermore, the substrate of the present invention may be such that a regularly arranged concave part is coated with a compound having water repellency group and the flat part is coated with a compound having water repellency group of which surface tension is smaller than that of a compound having a water repellency group. Such a substrate can also selectively adhere a biological substance having a hydrophobic group to the concave part. Such a constitution can be achieved, for example, by coating the concave part with a cyclicperfluoropolymer having an ether group along with coating the flat part with a fluoroalkylsilane compound or hydrolysate thereof. The cyclicperfluoropolymer having an ether group is exemplified by CYTOP (manufactured by Asahi Glass).

The substrate of the present invention is characterized by having concave parts regularly arranged. The shape, height, width, and density of the concave part may be any form necessary to the functional devices employing the substrate of the present invention. The shape of the concave part includes a spherical dent, a cone, a trigonal pyramid, a square pyramid, a groove, a cylinder, a line, a Y branched line and the like. When the arranged concave part is a spherical dent, a cone, a trigonal pyramid, a square pyramid, a groove, or a cylinder, the arranged concave parts are 4 or more per 1 cm², preferably 100 or more, and further preferably 10,000 or more. Moreover, in the case of a liner concave part, the line width is 3,000 micro-meter or less, preferably 10 micro-meter or less. Thus, the substrate having a highly densified fine pattern structure can be obtained.

The structure of the selectively adherent substrate of the present invention is not limited to the embodiment shown in FIG. 1. A structure forming a convex part 150 on the surface of the substrate 110 may be possible as shown in FIG. 4. For example, such a structure may be formed by stacking a layer of appropriate thickness on the substrate surface and then partially removing the layer. In such a structure, it may also be used as a substrate of the present invention by making the adherability to the specific substance on a convex part surface 152 different from that on the bottom or a slant face 154.

Furthermore, a part of the concave part of the substrate of the present invention may be water repellency. For example, in FIGS. 10A and 10B, exhibiting an expanded sectional view of a substrate surface part, water repellency film 144 may be set not only on the flat part 130 but the upper part in a concave part 120 as shown in FIG. 10A.

There exists the flat part on the substrate surface in the above example; however, when the concave part 120 is set densely as shown in FIG. 10B, water repellency film 146 may be set on a pointed crown part 132 although no flat part exists. Even where the concave part of the substrate surface is brought close and highly densified, and an area of the part having water repellency is relatively reduced, the selectively adherent substrate having a coupling portion excellent in quantitativity and reproducibility can be provided.

A method for producing the selectively adherent substrate of the present invention is described herein after. Principally, the concave part of the substrate surface is produced beforehand, followed by formation of a film with a material having the desired adherability to the concave part or the flat part.

As a method for producing the substrate having a regularly arranged concave part, exemplified is a combined method of a mask-pattern formation such as a photolithography, electron beam lithography, a proton-beam lithography, a X-ray lithography and the like, and a concave part formation such as a laser abrasion method, a wet etching method and the like.

As a method for forming the film on the substrate surface, a wet method and a dry method (vacuum method) can be exemplified.

The wet method can illustrate a spin-coating method, a dip-coating method, a spray-coating method, a flow-coating method, a meniscus-coating method, a gravure printing method, a flexographic printing method, a nano-imprinting method, a soft lithography method, a microcontact printing method and the like. The soft lithography method is particularly a simple and low cost method to selectively adhere a solution only to the flat part of the Substrate surface having the concave part.

The dry method (vacuum method) includes an evaporation method, a spattering method, an ion-beam method, a CVD method, a MOCVD method and the like. By combining these methods, the film can be formed with specified material to the specified part of the substrate surface.

The specific examples are described hereinafter.

### EXAMPLE 7

Cr film, and then Au film were consecutively formed by a spattering method on the quartz glass substrate (thickness 2 mm, size 50 mm×50 mm), followed by coating photoresist by a spin-coating method. Thereafter, the photoresist film was exposed with a pattern having apertures of 2500 in total arranged in a grid pattern such as 50 in the longitudinal direction and 50 in the transverse direction, followed by developing and then removing the exposed parts of the photoresist. Au film and Cr film were etched by using the photoresist as a mask to form apertures.

The glass substrate with the mask was washed with ultra pure water (specific resistance: 18 MΩ·cm), followed by etching with 49% hydrofluoric acid. Thereafter, the photoresist film was peeled off by NaOH aqueous solution after being washed by ultra pure water. Furthermore, the Cr mask was peeled away by using a nitric acid aqueous solution of diammonium cerium after the Au mask was peeled away by using an aqueous solution of iodine/ammonium iodide.

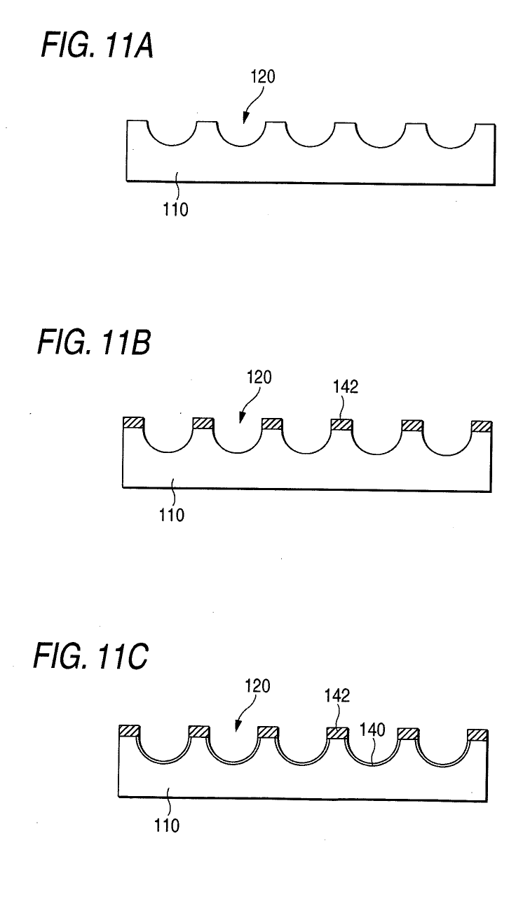

The appearance of the selectively adherent substrate obtained looked like the shape shown schematically in FIG. 1, and its cross sectional shape was schematically shown by FIG. 11A. The diameter of the spherical concave part was 50 μm, its density was 100/cm² (hereinafter, referred to as Substrate J).

Water repellent layer was formed on the flat part of substrate J by a soft lithography method described below.

The plate of polydimethylsiloxane (PDMS) having a smooth surface and thickness of approximately 1 mm was employed as a stamper. An alcohol solution or fluoroalkylsilane hydrolyzed by acid catalyst and water was poured in a flat-dish type vessel, followed by contact of one side of the stamper surfaces to the liquid. Thereafter, the stamper was made to contact with the surface or Substrate J to print the liquid on the stamper surface to the surface of Substrate J. Continuously, it was dried at a room temperature for 24 hours. Thus, a substrate in which a water repellent coating is formed on a flat part was obtained as shown in FIG. 11B (Substrate K).

By measurement of a contact angle with respect to water on the substrate, the angle was 105° at the surface or the flat part, and 10° at the surface of the concave part, and the difference in the contact angle with respect to water between the concave part and the flat part was 95°.

Then an ethanol solution of hydrolyzed aminopropyltriethoxysilane was prepared, followed by dipping Substrate K in the solution (so called dip-coating method) to selectively introduce an amino group only to the concave part as shown in FIG. 11C (Substrate L).

Substrate L introduced with the amino group selectively only to the concave part was dipped in aqueous solution of 1% glutaraldehyde at 4° C. for one hour to bridge the aminosilane group, followed by a reaction with FITC-protein A (manufactured by Zymed Lab.) in a phosphate buffer solution for 30 hours at 4° C. The FITC-protein A immobilized substrate (Substrate L1) was ultrasonically cleaned in the phosphate buffer solution for 10 seconds, followed by washing by pure water and than dried. By observation of the inside of the concave part and the flat part of Substrate L1 by a fluorescence microscope, fluorescence was observed at the area or 95% or more in the inside of the concave part, but the fluorescence observed on the flat part was less than 1% of the area thereof. The film thickness of the coated layer, since the layer was constituted with monomolecular level layer, was quite small compared with the diameter of the concave part. Consequently, R in the formula (1) can be approximated to A₁/A₂, and assumed as R>95.

Although the above described Substrate L was selectively introduced with the amino group only to the concave part, a mercapto group can be introduced to the concave part by employing mercaptopropyltrimethoxysilane in place of aminopropyltriethoxysilane. Moreover, a carboxyl group can be introduced by employing carboxylethylsilanetriol sodium salt or carboxylpropyltrimethoxysilane; or a hydroxyl group can be introduced, by hydroxyltrimethoxysilane.

Furthermore, a propyl group can be introduced by employing propyltrimethoxysilane; or a phenyl group can be introduced, by phenyltrimethoxyailane.

### EXAMPLE 8

Amino groups were selectively introduced in only concave parts of the substrate by a different manner from Example 1. The following 6 kinds among aminosilane compounds described above were used as aminosilane coupling agents.
(1) 3-aminopropyltriethoxysilane
(2) N-(2-aminoethyl)aminopropyltrimethoxysilane
(3) N-(2-aminoethyl)-11-aminoundecyltrimethoxysilane
(4) (aminoethylaminomethyl)phenethyltrimethoxysilane
(5) N-(5-aminohexyl)aminopropyltrimethoxysilane
(6) (3-trimethoxysilylpropyl)diethylenetriamine

Introduction of the amino group was carried out by the following procedures.

A micro titer plate having 96 wells made or glass was employed as a substrate A plate made of resin was also used for comparison. An acid solution (concentrated sulfuric acid: 30% hydrogen peroxide water=7:3) was separately injected to each of the concave parts for twelve hours. Then it was washed ten times with ion-exchange water, followed by washing one time with ultra pure water. Then a 3% aminosilane coupling agent was dissolved to 95% ethanol to form a solution, followed by 200 μl of the solution being separately injected to each concave part. After being reacted at a room temperature for one hour, it was washed with ethanol five times. Thereafter, it was calcined at 115° C. for one hour. Finally, it was washed with 95% ethanol, followed by drying. (Substrate M)

(Contact Angle Measurement)

The contact angle of the surface introduced with an amino group is generally increased due to the hydrophobic property of an alkyl chain which sustains an amino group. The results of contact angle measurement on the concave part of Substrate M are exhibited according to aminosilane from (1) to (6) in Table 4. The contact angles of the concave part of substrate M were around 80°, which were greater than that of a glass substrate surface and show the fact that the amino group was introduced.

TABLE 4

| Aminosilane | (1) | (2) | (3) | (4) | (5) | (6) |
|---|---|---|---|---|---|---|
| Contact angle | 82 | 82 | 86 | 83 | 72 | 74 |
| (Degree) | | | | | | |

(Analysis of Surface Atom)

Atoms existing on the surface of Substrate M were detected by an x-ray photoelectron spectroscopy (XPS). FIG. 9 exhibits atom concentrations on the substrate treated by aminosilane (2) and (6). Observed are carbon (C1s), nitrogen (N1s), oxygen (O1s) and silicon (Si2p) which are components of aminosilane. This result shows the presence of the amino group on the Substrate M surface.

TABLE 5

| Aminosilane | C1s | N1s | O1s | Si2p |
|---|---|---|---|---|
| (2) | 27.0 | 6.2 | 44.7 | 22.1 |
| (6) | 32.9 | 4.9 | 42.2 | 20.0 |

(Absorption of Protein)

By means of introduction or an amino group onto the glass surface, the amount of protein to be absorbed can be increased. The following is a description on of protein absorption onto the surface coated by 6 kinds aminosilane coupling agents.

Peroxidase (POD) was used as a protein to be absorbed. As an indicator for an absorbed amount, an increase in absorbance (wave length: 450 nm) caused by coloring of a reaction product was employed.

The absorption or POD was carried out according to the following procedures.

Initially, each concave part of Substrate M was separately injected by 100 μl of solution which was prepared by dissolving 0.05 μg/ml of POD in pH 7.4 of a phosphate buffer (PBS), followed by standing for 10 minutes. Then, removing the POD solution, followed by washing three times with 150 μl of pH 7.4 of PBS. Thereafter, 100 μl of a substrate solution of POD (3,3′,5,5′-tetramethylbenzidine (TMBZ), manufactured by Sumitomo Bakelite Co., Ltd.) was separately injected in each concave part. After 10 minutes elapsed, 100 μl of reaction termination solution (manufactured by Sumitomo Bakelite Co. Ltd.) was separately injected in each concave part.

After this treatment, absorbance was measured at a wave length of 450 nm. The absorbance measurement was carried out by using Fluorostar Optima (microplate reader). FIG. 3 exhibits measurement results of the untreated case and a case treated by aminosilane from (1) to (6). The ratios or the POD absorption amount to the untreated surface estimated from the absorbance result are shown in FIG. 4. According to those results, it is understood that, in almost all silane coupling agents used in the present invention, the absorbances have increased compared with the case of (1)3-aminopropyltriethoxysilane and the case of a coated resin.

TABLE 6

| Aminosilane | | | | | | | |
|---|---|---|---|---|---|---|---|
| Untreated | Untreated | (1) | (2) | (3) | (4) | (5) | (6) |
| Glass plate | 0.42 | 0.39 | 0.58 | 0.58 | 1.02 | 0.53 | 1.41 |
| Resin plate | 0.30 | 0.67 | 0.09 | 0.10 | 0.60 | 0.40 | 0.25 |

TABLE 7

| Aminosilane | | | | | | |
|---|---|---|---|---|---|---|
| Untreated | (1) | (2) | (3) | (4) | (5) | (6) |
| Glass plate | 0.94 | 1.38 | 1.39 | 2.46 | 1.26 | 3.38 |
| Resin plate | 2.27 | 0.32 | 0.33 | 2.02 | 1.33 | 0.85 |

When protein has to be absorbed much more on a substrate such as the case of a bioreactor, the present invention enables protein to be absorbed much more. This absorption increase is due to the fact that a positive charge is provided to a surface by the introduction of an amino group and interaction with a negative charge of protein.

The treatment method described above can be applied not only to peroxidase but other proteins. In particular, the absorption amount is expected to increase when an acidic protein having many negative charges on the surface thereof is used. Furthermore, not only protein but DNA can be absorbed. DNA can firmly bond with an amino group charging a positive charge due to DNA's negative charging. On account of such DNA bonding, an application for a highly sensitive DNA detection kit becomes possible.

(Immobilization of Protein)

By introducing an amino group to a glass surface, protein can be immobilized by covalent bonding. The following is a description about protein immobilization by bonding to the surface coated by 6 kinds of aminosilane coupling agents. As an indicator for the amount bonded, an increase of absorbance (wave length: 450 nm) caused by coloring of a reaction product was employed.

As well as the aforementioned manner, the bonding method is described using POD as an example. In each concave part of Substrate M introduced with an amino group, 100 μl of 2% glutaraldehyde solution to pH 7.4 of PBS was separately injected, followed by standing at 37° C. for two hours. This concave part was washed three times with 150 μl of ultra pure water.

Then, 100 ml of 0.1 mg/ml of biotin hydrazide solution to pH 7.4 of PBS was separately injected in each concave part, followed by standing at 37° C. for two hours. This concave part was washed three times with 150 μl of ultra pure water.

Thereafter, 150 μl of 3% of skit milk solution to pH 7.4 of PBS was separately injected in each concave part, and then the concave part was washed three times with 200 μl of pH 7.4 of PBS containing 0.05% of Tween 20. After this procedure, 100 ml of streptevidin (0.05 mg/ml) in which POD was bridge-bonded was separately injected in each concave part, and then the concave part was washed three times with 200 μl of pH 7.4 of PBS containing 0.05% of Tween 20. Furthermore, 100 μl of the substrate solution (TMBZ) of POD was separately injected in each concave part. After ten minutes elapsed, 100 μl of a reaction termination solution was separately injected in each concave part.

After this treatment, absorbance was measured at a wave length of 450 nm to obtain the ratio of a POD immobilized amount to an untreated case. The absorbance measurement results were exhibited in Table 8 and the ratios of the POD immobilized amount were exhibited in Table 9.

TABLE 8

| Aminosilane | | | | | | | |
|---|---|---|---|---|---|---|---|
| Untreated | Untreated | (1) | (2) | (3) | (4) | (5) | (6) |
| Glass plate | 0.69 | 0.75 | 0.93 | 0.36 | 1.28 | 0.46 | 1.13 |
| Resin plate | 0.43 | 0.05 | 0.13 | 0.13 | 0.27 | 0.18 | 0.71 |

TABLE 9

| Aminosilane | | | | | | |
|---|---|---|---|---|---|---|
| Untreated | (1) | (2) | (3) | (4) | (5) | (6) |
| Glass plate | 1.09 | 1.35 | 0.53 | 0.41 | 0.67 | 1.64 |
| Resin plate | 0.11 | 0.31 | 0.31 | 0.62 | 0.40 | 1.64 |

In almost all of the aminosilane coupling agents used in the present invention, the peroxidase immobilized amount increased compared with the case of coated resin. Especially, the cases of silane coupling agent (2) and (6) increased compared with the case of 3-aminopropyltriethoxysilane.

According to the method of the present invention, protein can be more greatly immobilized by covalent bonding compared with the resin plate. Such an increase of an immobilized amount results by the effective introduction of an amino group onto the substrate surface.

Although, in the above example, peroxidase was immobilized by utilizing a biotin-avidin bonding reaction, application of the ELISA (Enzyme-Linked Immunosorbant Assay) method which labels an antigen or antibody with enzyme and the like is also possible. According the results described above, development of a more sensitive ELISA is possible. Applications to a highly efficient microarray are expected.

### EXAMPLE 9

At the end of Example 8, an example to immobilize protein to an amino group by covalent bonding was shown, but in this Example, a procedure for more effective protein immobilization is described.

As the aminosilane coupling agent, (3-trimethoxysilylpropyl)diethylenetriamine was employed.

Acid solution (concentrated sulfuric acid: 30% hydrogen peroxide water=7:3) was separately injected to each concave part, followed by standing for three hours. Then, it was washed ten times with ion-exchange water, followed by washing one time with ultra pure water. Then a 3% aminosilane coupling agent was dissolved to 95% ethanol to form a solution, followed by 200 μl of the solution being separately injected to each concave part. After being reacted at a room temperature for one hour, it was washed with ethanol five times. Thereafter, it was calcined at 115° C. for one hour. Finally, it was washed with 95% ethanol, Followed by drying. (Substrate N)

POD was used as a protein, and immobilization and its evaluation were performed according to the same manner performed in Example B. Evaluation results of absorbance and the immobilized amount were exhibited in Table 10. It is understood that protein can be greatly immobilized in this Example.

Due to the increase in the immobilized amount, the targeted product can be produced more greatly in a biomicroreactor and detection can be made more highly sensitive in a test kit such as ELISA.

TABLE 10

| | Untreated | After treatment |
|---|---|---|
| Absorbance | 0.58 | 2.11 |
| Ratio of immobilized | — | 3.65 |
| amount | | |

### EXAMPLE 10

Cr film was formed by a spattering method on the quartz glass substrate (thickness 2 mm, size 50 mm×50 mm), followed by coating photoresist by a spin-coating method. Thereafter, the photoresist film was exposed with a pattern having apertures of 2500 in total arranged in a grid pattern such as 50 in the longitudinal direction and 50 in side direction, followed by developing and then removing the exposed parts of the photoresist. Cr film was etched by using the photoresist film as a mask to form apertures.

The glass substrate with the mask was washed with ultra pure water (specific resistance: 18MΩ·cm), followed by etching with 49% hydrofluoric acid. Thereafter, the photoresist film was peeled off by NaOH aqueous solution after being washed by ultra pure water.

Au film was formed on the whole area of the substrate by a spattering method. Thereafter, Cr mask was peeled away by using an aqueous solution of nitric acid diammonium cerium to obtain a substrate in which only the inside of the spherical concave part was coated by Au film. The film was formed on the flat part by using an alcohol solution of fluoroalkylsilane hydrolyzed by an acid catalyst and water by a soft lithography method employing FDXS as a stamper. After being dried at a room temperature for 24 hours, the contact angle with respect to water was measured resulting in 105° at the flat part surface (Substrate O).

In the concave part of Substrate O, DNA of which 5′-end was modified by biotin through a thiol derivative and avidin was immobilized according to the following procedure. First, Substrate O was dipped in 3 ml of aqueous solution of 3,3′-dithiodipropionic acid of 1 m mole concentration for 30 minutes. Resultantly, a carboxyl group was introduced to the Au film surface.

Then the substrate was dipped in a mixed aqueous solution of N-hydroxysuccinimide of 100 mg/ml and 1-ethyl-3-(3-dimethylaminopropyl)carbodiimide hydrochloride to react with the carboxyl group on the surface thereof for 30 minutes, followed by drying.

Thereafter, avidin was prepared to 0.2 mg/ml with a buffer solution (pH=8.0, 0.10 ml of Trio-hydrochoride, 0.2 mole of sodiumchloride), followed by dipping the substrate in 1 ml of the solution for one hour. Then, the substrate was dipped in 1 ml of aqueous, solution of ethanolamine of 1 mole concentration for 30 minutes to deactivate unreacted carboxyl group. By these procedures, Au film surface in the concave Part was modified by avidin.

The substrate was dipped in 1 ml of solution in which the biotinized DNA was prepared as one micro-mole concentration with the buffer solution (pH=8.0, 0.10 ml of Tris-hydrochloride, 0.2 mole of sodiumchloride), at 25° C. for 30 minutes to obtain the substrate immobilized with biotin-modified DNA (Substrate P).

Thereafter, in order to enhance fluorescence intensity for observation, DNAs were coupled to each other. Substrate P was dipped in 1 ml of solution in which FITC-modified DNA was diluted with a buffer solution (pH=7.9, 10 ml of Tris-hydrochoride, 0.2 mole of sodiumchloride), at 60° C. for 30 minutes to couple DNAs to each other.

The coupled DNA was confirmed by the observation of fluorescence by a fluorescence microscope (excited light 450 to 490 nm, absorbed light 515 to 565 mm). By observation with a fluorescence microscope inside the concave part and the flat part or Substrate P, fluorescence was observed at an area of 90% or more inside the concave part, but the fluorescence observed on the flat part was less than 1% of the area thereof. The film thickness of the coated layer, since the layered product was constituted with a monomolecular level layer, was quite small compared with the diameter of the concave part. Consequently, R in the formula (1) can be approximated to A₁/A₂, and was R>90.

### EXAMPLE 11

A hydrophobic-alkyl group was introduced to the concave part surface of the above described Substrate C according to the following method. An ethanol solution of 0.5% by weight of octadecyltrichlorosilane was hydrolyzed by acid and water to obtain a solution coating the concave part. By dipping Substrate O in the solution, the hydrolyzed octadecyltrichlorosilane was selectively adhered to the concave part. The substrate was dried in the air for 24 hours to obtain the substrate (Substrate Q) of which the concave part was hydrophobic and the flat part was water repellency.

Thereafter, in order to evaluate adherability, Substrate O was dipped in 1 ml of solution in which a protein having a hydrophobic group was diluted with 10 ml of Tris-hydrochoride added with 0-2 mole of sodium chloride, at 60° C. for 30 minutes. The protein having the coupled hydrophobic group was confirmed by observation of fluorescence by a fluorescence microscope (excited light 450 to 490 nm, absorbed light 515 to 565 nm), By the observation with the fluorezcence microscope on the inside of concave part and the flat part of Substrate O, fluorescence was observed at an area or 88% or more in the inside of concave part, but the fluorescence observed on the flat part was less than 1% of the area thereof. The film thickness or the coated layer, since the layered product was constituted with a monomolecular level layer, was quite small compared with the diameter of the concave part. Consequently, R in the formula (1) can be approximated to A₁/A₂, and was R>88.

### EXAMPLE 12

The concave part of the above described Substrate O was modified with a perfluorocyclicpolymer having an ether group according to the following method. A solution prepared by CYTOP (manufactured by Asahi Glass) being diluted with a solvent 100 times (in weight ratio) was dropped on the concave part of Substrate O, followed by drying at 85° C. for one hour. After being cooled down to a room temperature, the concave part was selectively coated by perfluorocyclicpolymer having an ether group. Thus, obtained was the substrate (Substrate R) in which surface tension of the flat part was smaller than that of the concave part.

Thereafter, in order to evaluate adherability, Substrate P was dipped in 1 ml of solution in which a protein having a hydrophobic group was diluted with 10 ml of Tris-hydrochoride added with 0.2 mole of sodium chloride, at 60° C. for 30 minutes. The protein having the coupled hydrophobic group was confirmed by observation of fluorescence by a fluorescence microscope (excited light 450 to 490 nm, absorbed light 515 to 565 mm) By observation with a fluorescence microscope on the inside of concave part and the flat part of Substrate P, fluorescence was observed at the area of 85% or more inside the concave part, but the fluorescence observed on the flat part was less than 1% of the area thereof. The film thickness of the adhered layer, since the layered product was constituted with a monomolecular level layer, was quite small compared with the diameter of the concave part. Consequently, R in the formula (1) can be approximated to A₁/A₂, and was R>85.

1. A selectively adherent substrate comprising;
a plurality of concave parts arranged with a predetermined pattern on a surface of the substrate,
wherein at least a part of a surface of each concave part has a liquid affinity different from a liquid affinity of a surface of another part on the surface of said substrate.

2. A selectively adherent substrate according to claim 1, wherein each concave part has a wettability different from a wettability of said another part on the surface of the substrate.

3. A selectively adherent substrate according to claim 1, wherein each concave part is formed by a recess formed on a flat surface of the substrate.

4. A selectively adherent substrate according to claim 1, wherein the surface said another part is water repellent.

5. A selectively adherent substrate according to claim 1, wherein a flat part is formed between the adjacent concave parts, a wettability of each concave part is different from a wettability of said flat part.

6. A selectively adherent substrate according to claim 5, wherein a surface of said flat part is water repellent.

7. A selectively adherent substrate according to claim 3, wherein said concave parts are arranged in a dense arrangement, a part of a surface of each concave part has a wettability different from a wettability of said another part.

8. A selectively adherent substrate according to claim 7, wherein the surface of said another part is water repellent.

9. A selectively adherent substrate according to claim 1, wherein a difference in contact angle to water between the surface of said concave part and the surface of said another part is more than 20°.

10. A selectively adherent substrate according to claim 9, wherein the difference in contact angle to water is more than 50°.

11. A selectively adherent substrate according to claim 10, wherein the difference in contact angle is more than 80°.

12. A selectively adherent substrate according to claim 4, wherein the water repellent surface of said another part is coated with at least one compound selected from a silicon compound containing an alkyl group or a silicon compound containing a fluoroalkyl group.

13. A selectively adherent substrate according to claim 1, wherein said concave parts are formed by
removing predetermined positions of a cover layer having a predetermined thickness covering a surface of a base substrate to form opening parts and to expose a surface of the base substrate, and
a surface of said concave part is formed by a side surface of said opening part and the surface of said basic substrate.

14. A selectively adherent substrate according to claim 13, a surface of said cover layer is water repellent.

15. A selectively adherent substrate according to claim 13, wherein the thickness of said cover layer is not less than 10 μm and not more than 100 μm.

16. A selectively adherent substrate according to claim 13, wherein a difference in contact angle to water between the surface of said basic substrate and the surface of said cover layer is more than 20°.

17. A selectively adherent substrate according to claim 16, wherein the difference in contact angle to water is more than 50°.

18. A selectively adherent substrate according to claim 17, wherein the difference in contact angle is more than 80°.

19. A selectively adherent substrate according to claim 13, wherein a light transmittance of said basic substrate is larger than two times of a light transmittance of said cover layer.

20. A selectively adherent substrate according to claim 19, wherein said cover layer includes a layer containing a black paint.

21. A selectively adherent Substrate according to claim 1, wherein a flat part is formed on said surface between the adjacent concave parts, wherein a surface tension of each concave part is different from a surface tension of said flat part.

22. A selectively adherent substrate according to claim 21, wherein the surface tension of said concave part is larger than the surface tension or said flat part.

23. A selectively adherent substrate according to claim 1, wherein a ratio of an adherent coefficient to a biological substance or a surface or each concave part to an adherent coefficient to the biological substance of said substrate is greater than 10.

24. A selectively adherent substrate according to claim 23, wherein a surface of said concave surface is coupled with a biological substance by at least one type of interaction selected from a covalent bond, a hydrogen bond, a static electrical interaction, a dipole-dipole interaction, a stacking interaction and a hydrophobic interaction.

25. A selectively adherent substrate according to claim 24, wherein the surface of said concave part has at least one type or functional group selected from an amino group, a mercapto group, a carboxyl group, a sulfonicacid group, a hydroxyl group, an alkyl group, a phenyl group and an ether group.

26. A selectively adherent substrate according to claim 23, wherein the surface of said another part is water repellent.

27. A selectively adherent substrate according to claim 26, wherein the water repellent surface of said another part is coated with at least one type selected from a silane compound containing an alkyl group or an aryl group, or a silane compound containing a fluoroalkyl group.

28. A selectively adherent substrate according to claim 23, wherein a difference in contact angle to water between the surface of each concave part and the surface of said another part is greater than 20°.

29. A method for producing a selectively adherent substrate including concave parts arranged with a predetermined pattern on a surface of said substrate, a flat part on the substrate surface between the adjacent concave parts, and a surface of said flat part being water repellent, the method comprising the steps of:
applying a solution containing a compound providing the water repellency on a stamper and
transferring the solution on the stamper to the flat part.

30. A method for producing a selectively adherent substrate including concave parts arranged with a predetermined pattern on a surface of said substrate, a flat part on the substrate surface between the adjacent concave parts, and a surface of said flat part being water repellent, the method comprising the steps of;
forming a water repellent coating containing a compound providing water repellency on a surface of said substrate;
forming a cover layer on said water repellent coating;
exposing a part of said water repellent coating by removing a part of said cover layer so as to form opening part;
etching said water repellent coating through said opening part by serving said cover layer as a mask; and
removing said cover layer.

31. A method for producing a selectively adherent substrate including concave parts arranged with a predetermined pattern on a surface of said substrate, a Slat part on the substrate surface between the adjacent concave parts, and a surface of said flat part being water repellent, the method comprising the steps of:
forming a water repellent coating containing a compound providing water repellency on a surface of said substrate:
forming a cover layer on said water repellent coating; and
exposing a part of said water repellent coating by removing a part of said cover layer so as to form opening part.

32. A method for producing a selectively adherent substrate according to claim 31, wherein a recess is formed on the exposed surface of the substrate by etching.
